(19) United States
(12) Patent Application Publication
(10) Pub. No.: US 2002/0190885 A1
(43) Pub. Date: Dec. 19, 2002

(54) Integrated apparatus for signal transmission and method therefor

(76) Inventor: Yu-Wei Lin, Taipei (TW)

Correspondence Address: RABIN & BERDO, P.C., Suite 500, 1101 14th Street, N.W., Washington, DC, 20005, US

(21) Appl. No.: 10/128,359

(22) Filed: Apr. 24, 2002

(30) Foreign Application Priority Data
Apr. 25, 2001 (TW) 90109953

(51) Int. Cl. H03M 1/66

(52) U.S. Cl. 341/144

(57) ABSTRACT

An integrated apparatus for signal transmission and method therefor. The integrated apparatus for signal transmission is adaptable to different data transfer rates and includes an Ethernet controller and a fast-Ethernet controller, a decoding device, and a current source module. The Ethernet controller can used for receiving a 10TXD signal and producing an adjustment signal by sampling the received 10TXD signal. The fast-Ethernet controller is used for receiving a 100TXD signal and a 100TXDN signal and producing an adjustment signal by sampling the received 100TXD and 100TXDN signal. In addition, the decoding device, according to a selection signal, is used to determine the data transfer rate and select one adjustment signal from the adjustment signals from the Ethernet and fast-Ethernet controllers. The selected adjustment signal is then fed into a current source module and an amplifier. The current source module supplies the amplifier with an operating current based on the selected adjustment signal, thereby producing either an approximation to a 10 Base-T signal or a 100 Base-T signal.

This application incorporates by reference of Taiwan application Serial No. 90109953, filed on Apr. 25, 2001.

### BACKGROUND OF THE INVENTION

1. Field of the Invention

The invention relates in general to an apparatus for signal transmission and a method therefor, and more particularly to an integrated apparatus for signal transmission, adaptable to different transmission rates simultaneously, and a method therefor.

2. Description of the Related Art

Currently, the quality of connection to the network such as the Internet or local area networks has been improved since high speed network connections and related hardware products become readily available. Users often require their products compliant with different network technologies, for example, network protocols at different data transfer rates. The speed of connection to the network depends on a number of factors. One main factor is the bandwidth that the network medium can provide. In addition to whether the network connection provides enough bandwidth, the transmission rate that a network interface card can support is an important factor. Under the present network architectures, local area networks (LANs), with respect to their protocols, can be categorized into Ethernet and fast-Ethernet. The Ethernet supports data transfer rates of 10 Mbps (i.e., 10 million bits per second) while the fast-Ethernet systems supports data transfer rates of 100 Mbps. Accordingly, the network interface cards have two different speeds respectively, depending on whether one is Ethernet or fast-Ethernet complaint. For examples with twisted-pair cabling scheme, Ethernet is referred to as 10 Base-T and the network interface cards compliant with 10 Base-T specification support the data transfer rates of 10 Mbps. In addition, fast-Ethernet is referred to as 100 Base-T, the 100 Base-T network interface cards support the data transfer rates of 100 Mbps. In theory, 100 Bast-T supports data transfer rates 10 times faster than that of 10 Bast-T, so the transmission efficiency can be greatly increased by using 100 Base-T. In practice, the two types of network interface cards are widely used, and, nowadays, integrated Ethernet/fast-Ethernet network interface cards have been developed and are available for computers to be connected with Ethernet and fast-Ethernet network systems.

FIG. 1 illustrates a conventional network interface card compliant with Ethernet and fast-Ethernet. In general, in a local host, a device driver for the network interface card of the host sends control commands to the physical layer (PHY) 130 of the network interface card through medium access control (MAC) 110 and medium independent interface (MII) 120. The PHY 130 includes, for example, six registers for configuring the network transfer status. Among the six registers, basic mode control register (BMCR) is the one to control the PHY 130. Under the present designed architecture, BMCR includes a speed selection (SPD) bit for setting the data transfer rate of the network interface card. For example, when the SPD bit is set to 0, indicating that the transfer data rate of the PHY 130 is set to 10 Mbps and data signal is transferred by a transceiver 140, wherein the transceiver is referred to as a transmitter and receiver. Conversely, when the SPD bit is set to 1, the data transfer rate of the PHY 130 is set to 100 Mbps and data signal is transferred by a transceiver 150. It should be noted that since 10 Base-T and 100 Base-T are two different communication protocols, having respective data transfer rates and signal waveforms, when it is required to upload data to the network, the Ethernet/fast-Ethernet network interface card needs to use one of the two different transceivers to process either 10 Base-T or 100 Base-T signal and to convert the signal into an output signal in either 10 Base-T or 100 Base-T format. In the following, the processes of transmission of 10 Base-T and 100 Base-T signal are described respectively.

FIG. 2 illustrates the conversion of a signal when the data transfer rate is at 10 Mbps. In FIG. 2, data coming from the PHY 130 are converted into a train of square pulses by Manchester encoding. For the sake of brevity, the Manchester encoded signal to be transmitted, hereinafter, is referred to as 10TXD signal. Since the data transfer rate is 10 Mbps, the pulse width of the square pulses is 50 ns. By an appropriate signal conversion process, the 10TXD signal is converted into a 10 Base-T signal, as shown in FIG. 2, to be outputted through a twisted-pair cable. In practice, 10 Base-T signals have a maximum amplitude of 2.5 V, i.e., the peak-to-peak voltage is 5V.

FIG. 3 illustrates the conversion of a signal when the data transfer rate is at 100 Mbps. In FIG. 3, data coming from the PHY 130 are converted into two different signals by multi-level transition 3 (MLT-3) encoding. For the sake of brevity, the two different MLT-3 encoded signals to be transmitted, hereinafter, are referred to as 100TXD signal and 100TXDN signal respectively. The 100TXD and 100TXDN signals are fed into the transceiver 150 so as to be converted into a 100 Base-T signal, as shown in FIG. 3, based on both the 100TXD and 100TXDN signals by an appropriate signal conversion process. The 100 Base-T signal is then outputted through a twisted-pair cable. In practice, 100 Base-T signals have a maximum amplitude of 1.0 V.

As can be seen from FIGS. 2 and 3, the Manchester encoded signal and MLT-3 encoded signal are digital signals while the 10 Base-T and 100 Base-T signals are analog signals. Accordingly, digital-to-analog signal conversion is required in the process of transmitting the data signal from the PHY 130. In practice, before being transmitted to the network, the 10TXD signal from the PHY 130 is fed into the transceiver 140 and a conversion circuit produces the 10-Base-T signal to be transmitted, based on the 10TXD signal. In addition, the 10 Base-T signal, which is specified to be analog, is approximately generated in a digital manner. For the MLT-3 encoded signal, when the PHY 130 feeds its 100TXD and 100TXDN signals into the transceiver 150, a conversion circuit is also needed to produce the 100 Base-T signal based on the 100TXD and 100TXDN signals. Likewise, the 100 Base-T signal, which is specified to be analog, is approximately produced in a digital manner. Since the 10 Base-T and 100 Base-T signals are produced approximately by digital manners, two different circuits are required. Accordingly, the integrated Ethernet/fast-Ethernet network interface card requires two different transceivers. Thus, the circuits for performing approximation to the 10 Base-T and 100 Base-T signals are essential to the transmission of signal. In the following, the digital-to-analog signal conversion is described.

FIG. 4A illustrates the digital-to-analog signal conversion for approximations of analog signals. A stair-stepped digital signal 410 in FIG. 4A is used as an approximation to an analog signal 420 having a positive half-cycle sinusoidal waveform. As can be seen from FIG. 4A along the X-axis, the analog signal 420 are divided into 10 equal divisions. Since the slope of the analog signal 420 is variable along the X-axis, successive “steps” of the digital signal 410 have respective increments when the digital signal 410 is increasing. Similarly, as the digital signal 410 is decreasing, its successive “steps” have respective decrements. For these cases, every “step” can be considered as a weighted sum and has specific weightings. Thus, for finding the nearest approximation to the analog signal, the approximation will have steps using different weightings when the analog signal has variable slope.

FIGS. 4A and 4B show two digital signals representing analog signals 420 and 440, wherein the amplitude of the analog signal 420 is larger than that of the analog signal 440. In FIG. 4A, the digital signal 410 is used as the approximation to the analog signal 420, having a sequence of weighted “steps” equal to 2, 6, 9, 11, 12, 12, 11, 9, 6, and 2, respectively. In FIG. 4B, the digital signal 430 is used as the approximation to the analog signal 440, having a sequence of weighted “steps” equal to 1, 2, 3, 4, 5, 5, 4, 3, 2, and 1 respectively.

Therefore, in general, when it is required to transmit data at a data transfer rate of 10 Mbps, a digital-to-analog conversion circuit should be used to produce an output signal that approximates 10 Base-T signal based on the 10TXD signal for the data to be transmitted. When it is required to transmit data at a data transfer rate of 100 Mbps, a digital-to-analog conversion circuit should be used to produce an output signal that approximates 100 Base-T signal based on the signals 100TXD and 100TXDN for the data to be transmitted. The 100 Base-T signal not only has a frequency 10 times larger than that of the 10 Base-T signal, but also has different waveform and amplitude from that of the 10 Base-T signal. Thus, the integrated Ethernet/fast-Ethernet network interface card, in practice, employs two different transceivers and cannot share a conversion circuit for both 10 Base-T and 100 Base-T.

In brief, the conventional integrated Ethernet/fast-Ethernet network interface card has at least the following disadvantages. (1) Two different transceivers are required for signal processing of 10 Base-T and 100 Base-T respectively, resulting in the finished product having an increased area and reduced competitiveness. (2) The use of the two transceivers causes increased stray capacitance in the output so that the output impedance becomes more capacitive and an impedance mismatch would occur, thus increasing the reflection signal and reducing the performance of signal transmission.

### SUMMARY OF THE INVENTION

It is therefore an object of the invention to provide an integrated apparatus for signal transmission, adaptable to different transmission rates. The integrated apparatus is capable of using one transceiver for signal processing of different formats, e.g., 10 Base-T and 100 Base-T, thus resulting in a reduction in chip area and enhancing competitiveness.

It is another object of the invention to provide an integrated apparatus for signal transmission, capable of reducing stray capacitance in the output, thus causing impedance match and improving transmission efficiency.

The invention achieves the above-identified objects by providing an integrated apparatus for signal transmission. The integrated apparatus includes an Ethernet controller, a fast-Ethernet controller, a decoding device, and a driving device. The Ethernet controller can be used for receiving a 10TXD signal and producing a first adjustment signal by sampling the 10TXD signal using a first sampling signal; the first adjustment signal is then fed into the decoding device. In addition, the fast-Ethernet controller is used for receiving a 100TXD signal and a 100TXDN signal, and producing a second adjustment signal by sampling the 10TXD and 100TXDN signals through a second sampling signal; the second adjustment signal is then fed into the decoding device. The decoding device, coupled to the Ethernet controller and the fast-Ethernet controller, is for receiving the two adjustment signals and selecting one of them according to a speed selection (SPD) bit so as to determine the data transfer rate of the output signal to be outputted by the decoding device. The driving device, coupled to the decoding device, is used for producing an output voltage, in response to the selected adjustment. The driving device includes an amplifier and a current source module, wherein the current source module is used for supplying the amplifier with different operating currents so as to produce the output voltage as the approximation to either a 10 Base-T or 100 Base-T signal. For instance, when the SPD bit is 0, the data transfer rate can be set to 10 Mbps so that the decoding device outputs the first adjustment produced by using the 10TXD signal. The first adjustment signal selected by the decoding device is fed into the current source module and the amplifier. The current source module outputs an output current based on the selected adjustment signal from the decoding device and feeds the output current into the amplifier so as to cause the amplifier to produce an output voltage approximating the 10 Base-T signal. When the SPD bit is 1, the data transfer rate can be set to 100 Mbps so that the decoding device outputs the second adjustment produced by using the 100TXD and 100TXDN signals. The second adjustment signal selected by the decoding device is fed into the current source module and the amplifier. The current source module outputs an output current based on the selected adjustment signal from the decoding device and feeds the output current into the amplifier so as to cause the amplifier to produce an output voltage approximating the 100 Base-T signal.

Other objects, features, and advantages of the invention will become apparent from the following detailed description of the preferred but non-limiting embodiments. The following description is made with reference to the accompanying drawings.

### BRIEF DESCRIPTION OF THE DRAWINGS

FIG. 1 shows a conventional Ethernet/fast-Ethernet network interface card.

FIG. 2 illustrates the signal conversion with a data transfer rate of 10 Mbps.

FIG. 3 illustrates the signal conversion with a data transfer rate of 100 Mbps.

FIGS. 4A and 4B illustrate the digital approximations to two sinusoidal waves with the same period but different amplitudes.

FIG. 5 illustrates a differential amplifier used in the invention.

FIG. 6 is a block diagram illustrating an integrated signal transmission device according to a preferred embodiment of the invention.

FIG. 7A illustrates the adjustment signal in FIG. 6 when the data transfer rate is 10 Mbps.

FIG. 7B illustrates the output signal based on the adjustment signal shown in FIG. 7A.

FIG. 7C illustrates the driving device in FIG. 6 when the data transfer rate is 10 Mbps.

FIG. 8A illustrates the adjustment signal in FIG. 6 when the data transfer rate is 100 Mbps.

FIG. 8B illustrates the output signal based on the adjustment signal shown in FIG. 8A.

FIG. 8C illustrates the driving device in FIG. 6 when the data transfer rate is 100 Mbps.

FIG. 9 illustrates a digital-to-analog conversion device according to the invention.

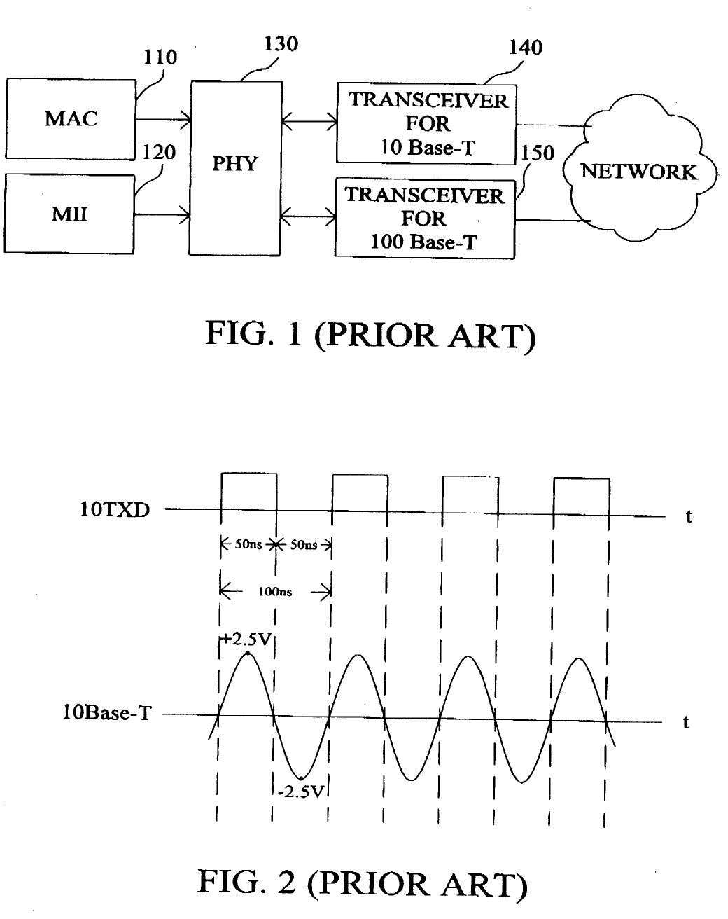

### DETAILED DESCRIPTION OF THE INVENTION

From the description above, the conventional integrated Ethernet/fast-Ethernet network interface card (NIC) requires two different transceivers since 10 Base-T and 100 Base-T requires different output waveforms, i.e., different signal levels and waveforms, resulting in the corresponding 10 Base-T and 100 Base-T signals that have steps with their different weightings. In order to overcome this problem of requiring two different transceivers, the invention employs a variable-current-source bias voltage amplifier. As an example, a differential amplifier can be configured to produce output voltages corresponding to the weightings for the 10 Base-T and 100 Base-T by changing the output of the current source that the differential amplifier is supplied with, thereby allowing a transceiver adaptable to the two required signals. In the following, the implementation with the variable-current-source bias voltage amplifier is described.

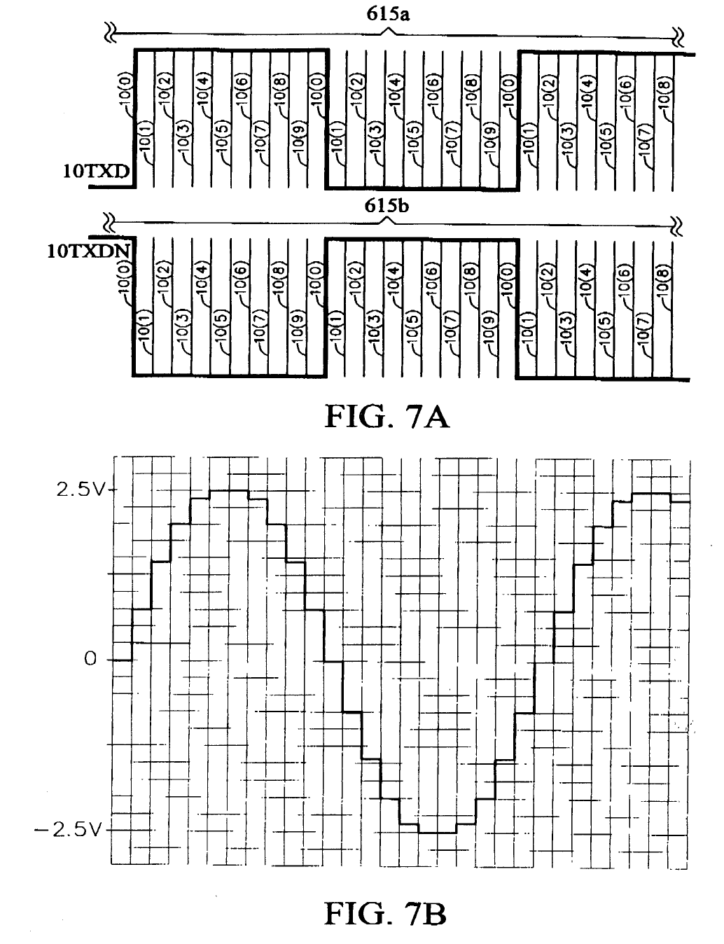

FIG. 5 shows a differential amplifier 500 for use in the invention. The differential amplifier 500 is biased by a current source 501. If V1 is greater than V2, the output voltage Vo of the differential amplifier 500 is a positive voltage. Conversely, if V1 is less than V2, the output voltage Vo is a negative voltage. If the current source 501 provides a larger current, the output voltage Vo (i.e. the absolute value of the amplitude of the output voltage Vo) becomes larger.

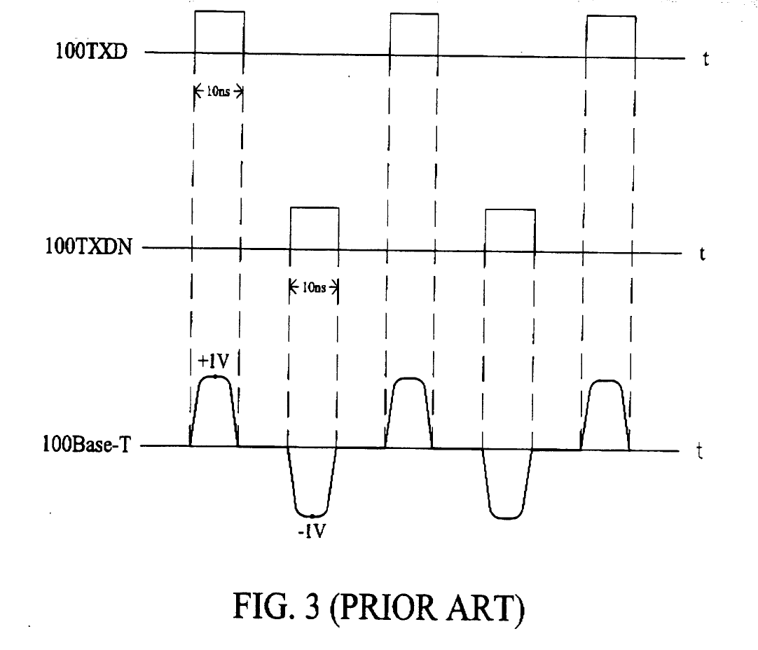

Referring to FIGS. 2 and 5, when the 10TXD signal is in a state of logic “1”, a positive voltage can be outputted by feeding the 10TXD signal into the gate of a transistor Q1 and grounding the gate of a transistor Q2. Conversely, when the 10TXD signal is in a state of logic “0”, a negative voltage can be outputted by feeding a signal indicating the inverted state of the 10TXD signal into the gate of the transistor Q2 and grounding the gate of the transistor Q1. In this way, corresponding positive and negative voltages can be obtained based on the signal levels of the 10TXD signal. With appropriate circuit design, the positive and negative voltages can be converted into the positive and negative half-cycle of sinusoidal waveforms, respectively. Accordingly, a corresponding 10 Base-T signal can be produced, based on the 10TXD signal. For achieving the conversion from logic “1” and logic “0” to positive and negative half-cycles of sinusoidal waveforms, one approach is, for example, to control two groups of current sources by switching current from one to another. As described above, the output voltage of the differential amplifier 500 is proportional to the output current from the current source 501. Thus, when the 10TXD signal in the high level is sampled and low-pass filtered to control the gate of the transistor Q1, the output voltage Vo can approximate a positive half-cycle of a sinusoidal waveform by switching current from group 1 to group 2 provided by the current source 501, in a step-by-step manner, according to a predetermined weighting, increasingly and then decreasingly. Conversely, when the high level signal is sampled and filtered to control the gate of the transistor Q2, the output voltage Vo can approximate a negative half-cycle of a sinusoidal waveform by switching current from group 2 to group 1 provided by the current source 501, in a step-by-step manner, increasingly and then decreasingly. Approximations of sinusoidal signals that correspond to Manchester codes can be obtained as the 10 Base-T signal.

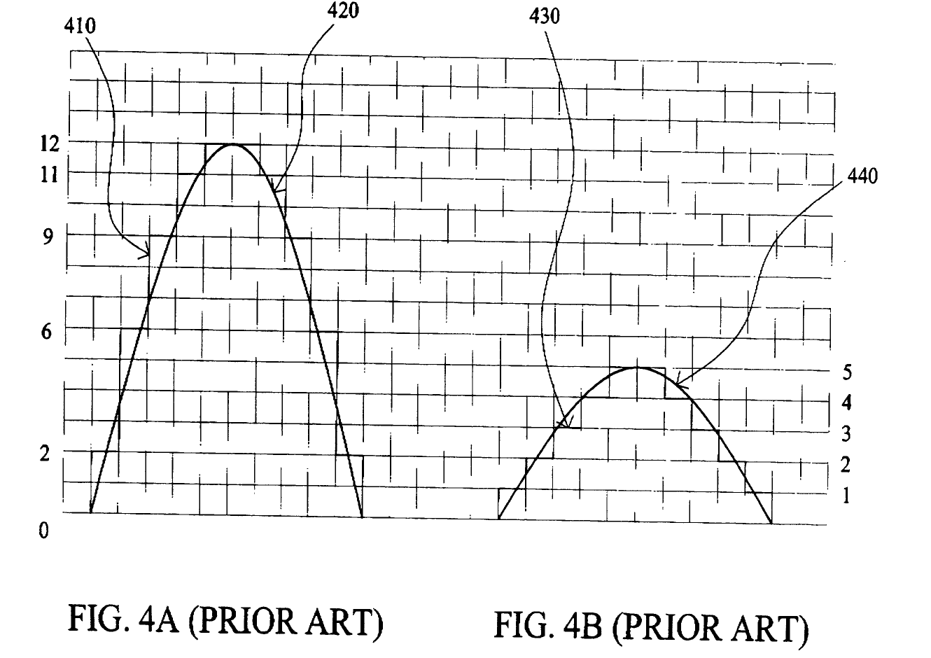

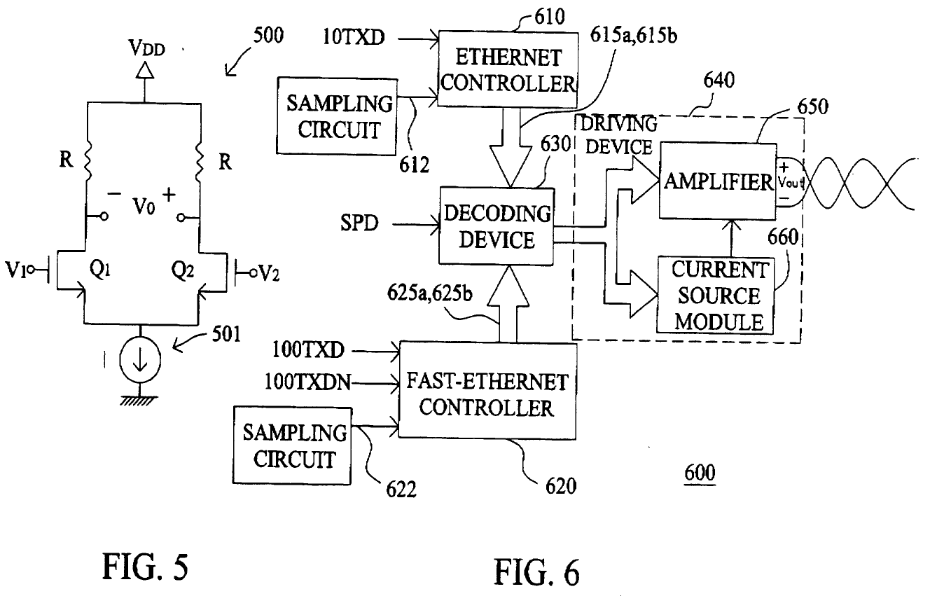

Referring to FIGS. 3 and 5, the 100TXD and 100TXDN signals are fed into the differential amplifier 500, i.e., the 100TXD signal is as the input signal V1 and 100TXDN signal is as the input signal V2. When the 100TXD signal is at a high level, a positive voltage can be outputted. When the 100TXDN signal is at a high level, a negative voltage can be outputted. When both the 100TXD and 100TXDN signals are at the low level, the output voltage is zero. In this way, the corresponding positive or negative voltage can be produced, based on the 100TXD and 100TXDN signals. The positive and negative voltages can be converted into a required MLT-3 waveform by a converting process. Thus, the 100 Base-T signal can be produced, based on the 100TXD and 100TXDN signals. In the process of converting the positive and negative voltages into the MLT-3 waveform, the variable current source can be employed similarly according to the process used for the 10 Base-T signal. When the 100TXD signal is at the high level, the current source 501 changes its output current, in a step-by-step manner, increasingly and then decreasingly, so that the output signal Vo that approximates a positive half-cycle of a 100-Base-T signal waveform is produced. Conversely, when the 100TXDN signal is at the high level, the current source 501 changes its output current, in a step-by-step manner, increasingly and then decreasingly, so that the output signal Vo that approximates a negative half-cycle of a 100-Base-T signal waveform. In this way, the 100 Base-T signal corresponding to the MLT-3 codes can be produced with deliberately designed changes in the current from the current source 501.

Accordingly, a key to the digital-to-analog conversions described above is whether the changes in the current from the current source, when being adjusted, for the differential amplifier are appropriately designed. For producing appropriate approximations to the 10 Base-T and 100 Base-T signals, weighted voltages are designed to correspond to the steps that approximate the 10 Base-T and 100 Base-T signals, respectively. The changes in current from the current source are made to correspond to weightings in voltage so as to produce the respective weighted voltages. In addition, the integrated apparatus for signal transmission are adaptable to both MLT-3 and Manchester encoded signal conversion so as to meet the signaling requirements for specific waveforms. For achieving the appropriate approximations, the output voltage waveform of an amplifier, as described above, is generated by a plurality of weighted voltage potentials for 10 Base-T and 100 Base-T signals, selectively. A current source module associated with a differential amplifier module is employed, for example. The current source module includes a plurality of current sources and the current sources supply different values of current corresponding to the weighted voltages for 10 Base-T and 100 Base-T. Since 10 Base-T and 100 Base-T signals have different waveforms, the current sources of the current source module are switched on or off selectively, so as to correspond to different weightings in voltage. With the current supplied by the current source module, the differential amplifier module can produce the weighted voltages for all steps that approximate 10 Base-T or 100 Base-T signal waveform. In particular, a 10 Base-T signal has an amplitude of 2.5 V and a 100 Base-T signal has an amplitude of 1.0 V. In this embodiment, the current source module, preferably, can be designed to produce a current corresponding to an output voltage of 2.5 V from the differential amplifier module by switching on all of its current sources. The current source module can be designed to produce a current corresponding to an output voltage of 1.0 V from the differential amplitude module by switching on a portion of its current sources. In this case, a 100 Base-T signal can be produced by using a subset of the current sources for 10 Base-T, thereby allowing a shareable signal conversion circuit for both 10 Base-T and 100 Base-T. Since this structure is capable of producing a plurality of weighted voltages according to the requirements for MLT-3 and Manchester encoded signal conversion, the objects of the invention can be achieved by this structure. The following is to describe the implementation of the structure.

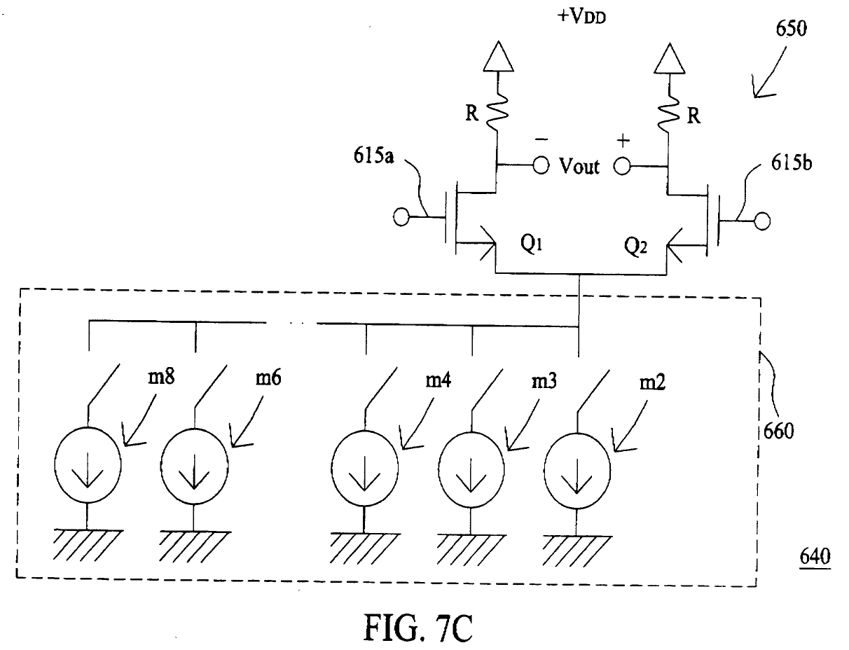

FIG. 6 shows an integrated signal transmission apparatus 600 according to a preferred embodiment of the invention. The integrated signal transmission apparatus 600 includes an Ethernet controller 610, a fast-Ethernet controller 620, a decoding device 630, and a driving device 640. The driving device 640 includes an amplifier module 650 and a current source module 660. Both the Ethernet controller 610 and the fast-Ethernet controller 620 are coupled to the decoding device 630. The decoding device 630 is coupled to the driving device 640. The decoding device 630 is coupled to the amplifier module 650 and the current source module 660 while the current source module 660 is coupled to the amplifier module 650. The current source module 660 is capable of generating an approximation to 10 Base-T signal or 100 Base-T signal, according to the adjustment signals 615a and 615b, or 625a and 625b, respectively.

The Ethernet controller 610 is capable of receiving 10TXD signals. By performing sampling with a sampling signal 612, the Ethernet controller 610 generates an adjustment signal 615a and an adjustment signal 615b. The adjustment signals 615a and 615b are then fed into the decoding device 630. In addition, the fast-Ethernet controller 620 is capable of receiving 100TXD and 100TXDN signals. By performing sampling with a sampling signal 622, the fast-Ethernet controller 620 generates an adjustment signal 625a and an adjustment signal 625b. The adjustment signals 625a and 625b are then fed into the decoding device 630. The decoding device 630 is capable of receiving adjustment signals at different rates. For determination of the data transfer rate of the output signals, the decoding device 630 is set to, for example, either 10 Mbps or 100 Mbps, according to a speed selection (SPD) bit. For example, if the SPD bit is set to 0, the data transfer rate is set to 10 Mbps so that the decoding device 630 outputs the adjustment signals 615a and 615b. Conversely, if the SPD bit is set to 1, the data transfer rate is set to 100 Mbps so that the decoding device 630 outputs the adjustment signals 625a and 625b. After the setting of the SPD bit, the output signals from the decoding device 630 are fed into the driving device 640, for example, to control the amplifier module 650 and the current source module 660. It should be noted that the current source module 660 is used for supplying operating current to the amplifier module 650 so that the amplifier module 650 outputs a predetermined output voltage signal. When the data transfer rate is set to 10 Mbps, the output current from the current source module 660 can be determined according to the adjustment signals 615a and 615b so that the amplifier module 650 produces an output voltage signal which approximates the corresponding 10 Base-T signal. When the data transfer rate is set to 100 Mbps, the output current from the current source module 660 can be determined according to the adjustment signals 625a and 625b, so that the amplifier module 650 produces an output voltage signal which approximates the corresponding 100 Base-T signal. It should be noted that the amplifier module 650 can be a differential amplifier, or any other amplifying circuit capable of performing the same function as the amplifier module 650, such as an inverting amplifier, a non-inverting amplifier, or an instrumentation amplifier. For the sake of brevity and simplicity, in the following description, a differential amplifier is used as the amplifier module 650. Certainly, the use of differential amplifier is not to restrict the range of applications of the invention.

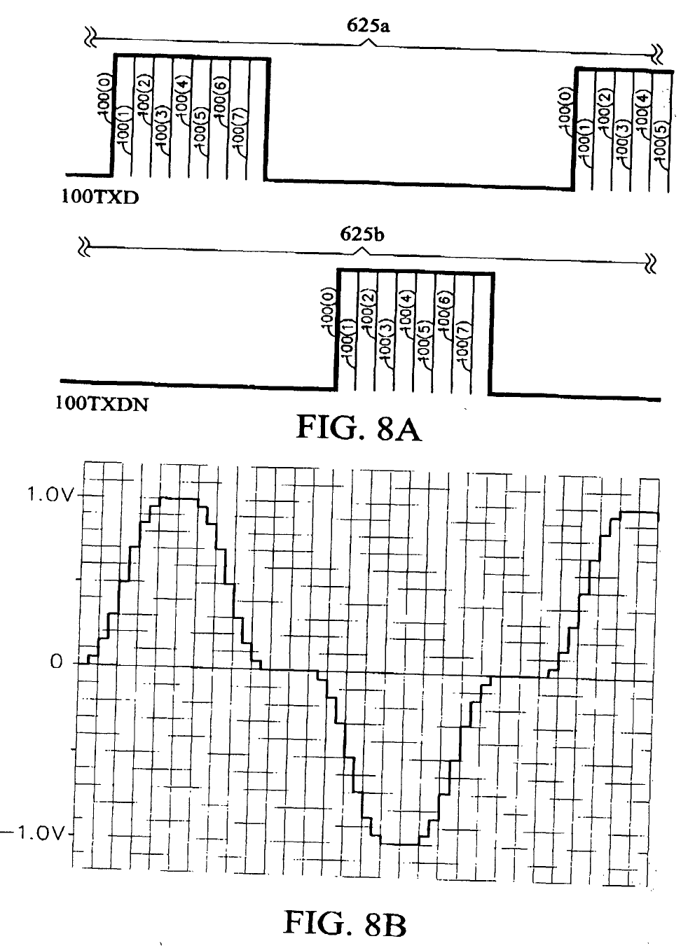

The processing of a 10TXD signal as the data transfer rate is set to 10 Mbps is described. When a 10TXD signal is fed into the Ethernet controller 610, it is sampled by using the sampling signal 612 so as to produce the adjustment signal 615a. The sampling signal 612, for example, can be indicative of 10 separate clock signals, at a predetermined frequency, sequentially shifted with an equal phase delay (e.g. 5 ns). By the sampling signal 612 indicative of the 10 separate clock signals, the 10TXD signal at either a high level (state 1) or a low level (state 0) can be divided into 10 separate pulses having respective intervals corresponding to the 10TXD signal's status sampled by the corresponding clock signals so as to form the adjustment signal 615a. Note that the adjustment signal 615a is produced by sampling the 10TXD signal by using the sampling signal 612 that indicates the 10 separate clock signals, and that the adjustment signal 615a is thus indicative of a plurality of separate pulse signals, wherein the 10TXD signal is represented by a bold line in the upper portion of FIG. 7A. In addition, in FIG. 7A, the separate pulses indicated by the adjustment signal 615a are marked with their rising edges, with respect to the time in sequence, drawn consecutively as pulses 10(0), 10(1), 10(2), . . . , and 10(9), for the sake of simplicity. When the 10TXD signal is at the high level, the adjustment signal 615a is at a high level; that is, each of the pulses 10(0) to 10(9) is at a high level for a specific pulse width (i.e. an specific interval), respectively. Conversely, when the 10TXD signal is at the low level, the adjustment signal 615a is at a low level; that is, each of the corresponding pulses 10(0) to 10(9) is at a low level for a specific pulse width, respectively. The pulse 10(0) is indicative of the zeroth sampled point of the 10TXD signal. The pulse 10(1) is indicative of the first sampled point of the 10TXD signal. The pulse 10(2) is indicative of the second sampled point of the 10TXD signal. The pulse 10(9) is indicative of the ninth sampled point of the 10TXD signal. That is to say that the adjustment signal 615a includes the pulses 10(0) to 10(9). Therefore, since the sampling signal 612 includes 10 separate clock signals with different phrases, the signal level of each of the pulses corresponds to the status of the 10TXD signal. In addition, each of the pulses maintains at the level of the associated sampled point, for example, as indicated by the mark in FIG. 7A, for a specific interval.

In brief, the adjustment signal 615a may include 10 separate pulse signals with different phases, consecutively. In addition, the 10TXD signal is inverted and the inverted 10TXD is referred to as a 10TXDN signal, as shown in the lower part of FIG. 7A in bold line. The 10TXDN signal is sampled by the sampling signal 612 that, for example, includes the 10 separate clock signals so as to produce the adjustment signal 615b. The adjustment signal 615b thus includes pulses 10(0), 10(1), 10(2), . . . , 10(9). Note that the pulses of the adjustment signal 615b, as shown in the lower part of FIG. 7A, are represented with the same marks as that of the adjustment signal 615a but are of opposite phase to that of the adjustment signal 615a, respectively. As will be illustrated later, the output signal of the integrated signal transmission apparatus 600, when 10 Base-T signal is required, is produced in response to the sample result of the 10TXD signal sampled by the sampling signal 612.

FIGS. 7A to 7C illustrate digital-to-analog conversion of the invention when the data transfer rate is 10 Mbps. Referring to FIG. 7C, the adjustment signals 615a and 615b are fed into the differential amplifier module 650, respectively. When the adjustment signal 615a is at the high level, the adjustment signal 615b is at the low level, resulting in a positive output voltage Vout. Conversely, when the adjustment signal 615a is at the low level, the adjustment signal 615b is at the high level, resulting in a negative output voltage Vout.

In the following, the process of the generation of the output voltage Vout is described.

It is first to explain how the output voltage Vout is produced when the adjustment signal 615a is at the high level. As shown in FIG. 7C, the current source module 660 includes a plurality of current sources, for producing different values of current, wherein labels m2, m3, m4, and so on are assigned to the current sources. By using different combination of the current sources, a number of different values of current can be produced. The labels assigned to the current sources are to indicate that an output voltage variation corresponding to a weighting can be produced when a specific current source is enabled or disabled for biasing the differential amplifier module 650. For instances, a positive output voltage difference corresponding to a weighting of 2 can be produced when the current source m2 is used for biasing the differential amplifier module 650; an output voltage difference corresponding to a weighting of 3 can be produced when the current source m3 is used for biasing the differential amplifier module 650. Thus, when the current sources m2 and m4 are turned on, an output voltage difference corresponding to a weighting of 6 is produced.

In addition, the operation of the circuit shown in FIG. 7C is described. When the pulse 10(0) is fed into a transistor Q1 of the differential amplifier module 650, the current source m2 can be turned on by using appropriate circuit design, such as a switch as shown in FIG. 7C, according to the pulse 10(0), and produces an output voltage difference on Vout corresponding to the weighting of 2. Likewise, the pulse 10(1) can cause the current sources m2 and m4 to turn on and output an output voltage difference corresponding to the weighting of 6, for example, by turning on switches connected to the current sources m2 and m4. The pulse 10(2) can cause the current sources m3 and m6 to turn on and output an output voltage difference corresponding to a weighting of 9. The pulse 10(3) can cause the current sources m3 and m8 to turn on and output an output voltage difference corresponding to the weighting of 11. The pulse 10(4) can cause the current sources m4 and m8 to turn on and output an output voltage difference corresponding to a weighting of 12. The pulse 10(5) can cause the current sources m4 and m8 to turn on and output an output voltage difference corresponding to the weighting of 12. The pulse 10(6) can cause the current sources m3 and m8 to turn on and output an output voltage difference corresponding to the weighting of 11. The pulse 10(7) can cause the current sources m3 and m6 to turn on and output an output voltage difference corresponding to the weighting of 9. The pulse 10(8) can cause the current sources m2 and m4 to turn on and output an output voltage difference corresponding to the weighting of 6. The pulse 10(9) can cause the current source m2 to turn on and output an output voltage difference corresponding to the weighting of 2 on the output voltage Vout.

Next, it is to explain how the output voltage Vout is produced when the adjustment signal 615a is at the low level. In this case, the adjustment signal 615b is at the high level and fed into a transistor Q2 of the differential amplifier module 650; that is, the pulse 10(0) of the adjustment signal 615b is fed into the transistor Q2. Thus, the current source m2 can be turned on by utilizing, for example, switches as shown in FIG. 7C, and produce an output voltage difference corresponding to the weighting of 2 on the output voltage Vout, wherein the output voltage difference is of opposite polarity to that corresponding to the weighting of 2 when the adjustment signal 615a is at the high level, in this embodiment. Likewise, the pulse 10(1) can cause the current sources m2 and m4 to turn on and output a negative output voltage difference corresponding to the weighting of 6 on the output voltage Vout. The pulse 10(2) can cause the current sources m3 and m6 to turn on and output a negative output voltage difference corresponding to a weighting of 9 on the output voltage Vout. The pulse 10(3) can cause the current sources m3 and m8 to turn on and output a negative output voltage difference corresponding to the weighting of 11 on the output voltage Vout. The pulse 10(4) can cause the current sources m4 and m8 to turn on and output a negative output voltage difference corresponding to a weighting of 12 on the output voltage Vout. The pulse 10(5) can cause the current sources m4 and m8 to turn on and output a negative output voltage difference corresponding to the weighting of 12 on the output voltage Vout. The pulse 10(6) can cause the current sources m3 and m8 to turn on and output a negative output voltage difference corresponding to the weighting of 11 on the output voltage Vout. The pulse 10(7) can cause the current sources m3 and m6 to turn on and output a negative output voltage difference corresponding to the weighting of 9 on the output voltage Vout. The pulse 10(8) can cause the current sources m2 and m4 to turn on and output a negative output voltage difference corresponding to the weighting of 6 on the output voltage Vout. The pulse 10(9) can cause the current source m2 to turn on and output a negative output voltage difference corresponding to the weighting of 2 on the output voltage Vout.

In particular, a sequence with the weightings, 2, 6, 9, 11, 12, 12, 11, 9, 6, and 2, is made for the approximation of a 10 Base-T signal. The weightings in the sequence are considered as the ratio among the required increments (or decrements) of voltages for consecutive steps that approximate a portion of the waveform compliant with 10 Base-T. With this sequence of weightings, an approximation for any 10 Base-T signal indicative of a data stream can be produced. In addition, the differential amplifier module 650 can be designed to produce a weighted output voltage of 2.5 V (a maximum voltage of 10 Base-T signals) corresponding to a combination of the weightings in the sequence, and a weighted output voltage of 2.5 V (a minimum voltage of 10 Base-T signals) corresponding to another combination of the weightings. Likewise, the weighted output voltage for every step according to a sinusoidal waveform can be defined as a corresponding combination of the weightings. Thus, an approximation to a 10 Base-T signal can be produced, corresponding to a 10TXD signal. For example, FIG. 7B is an approximation to a 10 Base-T signal corresponding to a data stream indicated by the 10TXD signal shown in FIG. 7A.

In practice, a 10 Base-T signal is a differential signal, that is, the output voltage Vout is the difference of the single-ended output voltages V1 and V2 of the differential amplifier module, where the voltages V1 and V2 have a common voltage. In one embodiment, the differential amplifier module 650 and the current source module 660 can be implemented with two sets of differential pairs, and each of the differential pairs is biased with a respective current source, controlled by a pulse signal of the adjustment signals, that is, the adjustment signals 615a and 615b. In other words, the two set of current sources are controlled by the corresponding differential pairs according to the adjustment signals (i.e. pulse 10(0) to 10(9)) so as to provide predetermined amounts of current for producing a plurality of voltage potential for the steps in the waveform. One set of current sources, or called the first set of current sources, is configured to provide currents for producing increments of voltage, veᵢ, corresponding to the weightings, while the other set of current sources, or called the second set of current sources, is configured to provide currents for producing decrements of voltage, −veᵢ, corresponding to the weightings, wherein veᵢ>0 and the subscript i denotes a weighting for a step in an approximation of waveform.

Referring to FIG. 7B, when the signal is stepped by a plurality of steps to reach a weighed voltage of −2.5 V for 10 Base-T; preferably, the second set of current sources is enabled to provide a sufficient current. In this embodiment, the supplied current should be varied in a step-by-step manner in order to meet the circuit stability and hardware characteristics. Thus, the signal reaches a voltage of −2.5 V in a step-by-step manner. When −2.5 V is reached, the decrements of voltages that correspond to the weightings 2, 6, 9, 11, 12, 12, 11, 9, 6, and 2 are all produced. After the signal reaches the point of −2.5 V for a period for a step (or called a step period), it increases by a voltage potential corresponding to the weighting of 2, that is, ve₂. At least one of the first set of current sources is to be enabled, corresponding to the weighting of 2. Thus, the signal reaches a voltage of −2.5+ve₂. After a step period, the signal increases by a voltage potential corresponding to the weighting of 6. A number of the first set of current sources are selected to produce ve₆, resulting in the signal reaching a voltage of −2.5+ve₂+ve₆. Following the same way, the signal reaches 0 V as the increments of voltages corresponding to the weightings of 2, 6, 9, 11 and 12 are produced. In terms of the notation of vᵢ, the relationship can be expressed by Vout=−2.5+ve₂+ve₆+ve₉+ve₁₁+ve₁₂=0. Finally, the signal reaches +2.5 V when the increments of voltages corresponding the weightings of 2, 6, 9, 11, 12, 12, 11, 9, 6, and 2 are all produced. The relationship can be expressed by Vout=−2.5+ve₂+ve₆+ve₉+ve₁₁+ve₁₂+ve₁₂+ve₁₁+ve₉+ve₆+ve₂=2.5. After the signal reaches 2.5 V for a step period, it decreases by a voltage potential corresponding to the weighting of 2, that is, −ve₂. At least one of the second set of current sources is to be enabled, corresponding to the weighting of 2. Thus, the signal reaches a voltage of 2.5+(−ve₂). In this way, the signal reaches −2.5 V when the decrements of voltages corresponding the weightings of 2, 6, 9, 11, 12, 12, 11, 9, 6, and 2 are all produced. The relationship can be expressed by Vout=2.5−ve₂−ve₆−ve₉−ve₁₁−ve₁₂−ve₁₂−ve₁₁−ve₉−ve₆−ve₂=−2.5. Therefore, the waveform compliant with 10 Base-T can be produced approximately according to the invention.

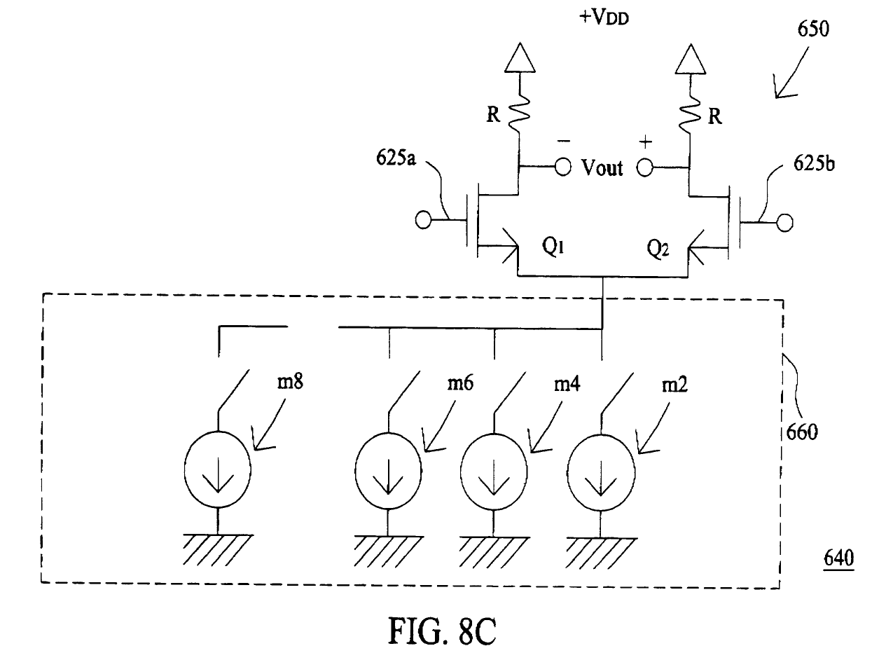

The processing of 100TXD and 100TXDN signals as the data transfer rate is set to 100 Mbps is described. A 100TXD signal and a 100TXDN signal are fed into the fast-Ethernet controller 620, and are sampled with the sampling signal 622 so as to produce the adjustment signals 625a and 625b. The sampling signal 622, for instance, can be indicative of 8 separate clock signals at a predetermined frequency, sequentially shifted with an equal phase delay (e.g. 0.8 ns), and used to sample 100TXD and 100TXDN signals at eight sample points for each 100 TXD pulse or each 100 TXDN pulse, as illustrated by the adjustment signals 625a and 625b. The adjustment signal 625a, as illustrated in the upper portion of FIG. 8A, shows the result of sampling the 100TXD signal sampled by the sampling signal 622 including the 8 clock signals, and is thus indicative of a plurality of separate pulse signals, wherein the 100TXD signal is represented by a bold line in the upper portion of FIG. 8A. In addition, the adjustment signal 625b shows the result of sampling the 100TXDN signal sampled by the sampling signal 622 that indicates the 8 clock signals, and is thus indicative of a plurality of separate pulse signals, wherein the 100TXDN signal is represented by a bold line in the lower portion of FIG. 8A. In FIG. 8A, the pulses included in the adjustment signals 625a and 625b are marked with their rising edges only (the falling part is not shown for clarity), with respect to the time in sequence, drawn consecutively as pulses 100(0), 100(1), 100(2), 100(3), . . . , and 100(7), for the sake of simplicity. The meaning of the labels here is identical to that applied in FIG. 7A. When the 100TXD signal is at a high level, the pulses 100(0) to 100(7) sample the 100TXD signal at a high level. In other words, each sample on the high level of 100TXD signal can produce a pulse at the high level for a specific pulse width. Similarly, when the 100TXDN signal is at a high level, each sample on the high level of 100TXDN signal can produce a pulse at the high level for a specific pulse width.

FIGS. 8A to 8C illustrate digital-to-analog conversion of the invention when the data transfer rate is 100 Mbps. Referring to FIG. 8C, the adjustment signals 625a and 625b are fed into the differential amplifier module 650, respectively. When the adjustment signal 625a is at a high level, the adjustment signal 625b is at a low level, resulting in the positive output voltage difference Vout. Conversely, when the adjustment signal 625a is at the low level, the adjustment signal 625b is at the high level, resulting in the negative output voltage difference Vout.

In the following, the process of the generation of the output voltage Vout is described.

It is first to explain how the output voltage Vout is produced when the adjustment signal 625a is at the high level. The current source module 660 in FIG. 8C includes a plurality of current sources, for producing different values of current. By using different combination of the current sources, a plurality of different values of current can be produced. The operation of the circuit in FIG. 8C is as follows. When the pulse 100(0) is fed into the transistor Q1, the current source m2 can be turned on through appropriate circuit design, by controlling switches as shown in FIG. 8C, to produce an output voltage difference corresponding to a weighting of 2 on the output voltage Vout. Likewise, the pulse 100(1) can cause the current source m4 to turn on and output an output voltage difference corresponding to a weighting of 4 on the output voltage Vout. The pulse 100(2) can cause the current source m6 to turn on and output an output voltage difference corresponding to a weighting of 6 on the output voltage Vout. The pulse 100(3) can cause the current source m8 to turn on and output an output voltage difference corresponding to a weighting of 8 on the output voltage Vout. The pulse 100(4) can cause the current source m8 to turn on and output an output voltage difference corresponding to the weighting of 8 on the output voltage Vout. The pulse 100(5) can cause the current source m6 to turn on and output an output voltage difference corresponding to the weighting of 6 on the output voltage Vout. The pulse 100(6) can cause the current source m4 to turn on and output an output voltage difference corresponding to the weighting of 4 on the output voltage Vout. The pulse 100(7) can cause the current source m2 to turn on and output an output voltage difference corresponding to the weighting of 2 on the output voltage Vout.

Next, it is to explain how the output voltage Vout is produced when the adjustment signal 625b is at the high level. When the pulse 100(0) is fed into the transistor Q2, the current source m2 can be turned on, through appropriate circuit design, for example, by controlling switches as shown in FIG. 8C, and produce a negative output voltage difference corresponding to the weighting of 2 on the output voltage Vout. Likewise, the pulse 100(1) can cause the current source m4 to turn on and output a negative output voltage difference corresponding to the weighting of 4 on the output voltage Vout. The pulse 100(2) can cause the current source m6 to turn on and output a negative output voltage difference corresponding to the weighting of 6 on the output voltage Vout. The pulse 100(3) can cause the current source m8 to turn on and output a negative output voltage difference corresponding to the weighting of 8 on the output voltage Vout. The pulse 100(4) can cause the current source m8 to turn on and output a negative output voltage difference corresponding to the weighting of 8 on the output voltage Vout. The pulse 100(5) can cause the current source m6 to turn on and output a negative output voltage difference corresponding to the weighting of 6 on the output voltage Vout. The pulse 100(6) can cause the current source m4 to turn on and output a negative output voltage difference corresponding to the weighting of 4 on the output voltage Vout. The pulse 100(7) can cause the current source m2 to turn on and output a negative output voltage difference corresponding to the weighting of 2 on the output voltage Vout.

If both the adjustment signals 625a and 625b are at low levels, by the characteristic of differential amplifiers, the output voltage Vout of the differential amplifier module 650 is zero.

In particular, a sequence with the weightings, 1, 2, 4, 8, 8, 4, 2, and 1, can be made for the approximation of a 100 Base-T signal. Another sequence with weightings, 2, 4, 6, 8, 8, 6, 4, and 2, which is equivalent to a sequence of weightings 1, 2, 3, 4, 4, 3, 2, and 1, for example, can also be made for a nearer approximation of a 100 Base-T signal. The weightings in one of the sequences of weightings for 100 Base-T signal approximation represent the required increments (or decrements) of voltages for consecutive steps that approximate the waveform compliant with 100 Base-T. With the sequence of weightings, an approximation to any 100 Base-T signal indicative of a data stream can be produced. In this embodiment, the differential amplifier module 650 can be designed to produce a weighted output voltage of 1.0 V (a maximum voltage of 100 Base-T signals) corresponding to a combination of the weightings from the sequence of weightings, and a weighted output voltage of −1.0 V (a minimum voltage of 100 Base-T signals) corresponding to another combination of the weightings from the same sequence of weightings. In this way, the weighted output voltage for every step according to a 100 Base-T waveform can be defined as a corresponding combination of the weightings. Therefore, an approximation to a 100 Base-T signal can be produced, corresponding to a 100TXD and 100TXDN signal. For example, FIG. 8B is an approximation to a 100 Base-T signal corresponding to a data stream indicated by the 100TXD and 100TXDN signals shown in FIG. 8A.

In practice, a 100 Base-T signal is a differential signal, that is, the output voltage Vout is the difference of single-ended output voltages V1 and V2, where V1 and V2 may have a common voltage. In one embodiment, the differential amplifier module 650 and the current source module 660 can be implemented with two sets of differential pairs, as same as mentioned above for the 10 Base-T signal approximation, and each of the differential pairs is biased with a respective current source, controlled by a pulse signal of the adjustment signals, that is, the adjustment signals 625a and 625b. In other words, the two set of current sources are controlled by the corresponding differential pairs according to the adjustment signals (i.e. pulse 100(0) to 100(9)) so as to provide predetermined amounts of current for producing a plurality of voltage potential for the steps in the waveform. One set of current sources, or called the first set of current sources, is configured to provide currents for producing increments of voltage, vfᵢ, corresponding to the weightings, while the other set of current sources, or called the second set of current sources, is configured to provide currents for producing decrements of voltage, −vfᵢ, corresponding to the weightings, wherein vfᵢ>0 and the subscript i denotes a weighting for a step in an approximation of waveform compliant with 100 Base-T.

Referring to FIG. 8B, the signal on the left end of FIG. 8B corresponding to a weighed voltage of 0 V increases by a positive voltage potential corresponding to a weighting of 2 (i.e., vf₂), when the signal 100TXD changes from the state 0 to state 1, as shown in the upper part of FIG. 7A, for example. For increasing the signal by vf₂, the first set of current sources is selectively enabled to provide a current for producing the weighted voltage, thus causing the signal to generate vf₂. After a step period, the signal increases by a voltage potential corresponding to the weighting of 4,and thus reaches a voltage of vf₂+vf₄. The signal continues to be increased incrementally so as to reach a voltage of 1.0 V in a step-by-step manner. When the signal reaches +1.0 V, the increments of voltages that correspond to the weightings 2, 4, 6, 8, 8, 6, 4, and 2 are all produced. In terms of the notation of vfᵢ, the relationship can be expressed by Vout=vf₂+vf₄+vf₆+vf₈+vf₈+vf₆+vf₄+vf₂=1.0 V. After the signal reaches the point of 1.0 V for a number of step periods (which depends on the pulse width of the pulses in the adjustment signal 625a and 625b), it begins to drop to zero voltage in a step-by-step manner because the current sources corresponding to the increments of voltages begin to be disabled, consecutively. According to the transition of the pulses from the state 1 to state 0, the current sources controlled by the pulses 100(0), 100(1), . . . , and 100(7) are to be disabled successively. For example, the signal, immediately after having a voltage of 1.0 V for several step periods, decreases by a voltage potential corresponding to the weighting of 2 (i.e. vf₂), by disabling the corresponding current sources among the first set of current sources. The signal then has a voltage of 1.0−vf₂. After a step period, the signal decreases by a voltage potential corresponding to the weighting of 4 (i.e. vf₄), resulting in the signal reaching a voltage of 1.0−vf₂−vf₄. Likewise, the signal returns to 0 V when the current sources for providing currents for the increments of voltages corresponding to the weightings of 2, 4, 6, 8, 8, 6, 4, and 2 are all disabled. In terms of the notation of vfᵢ, the relationship can be expressed by Vout=1.0−vf₂−vf₄−vf₆−vf₈−vf₈−vf₆−vf₄−vf₂=0.

When the signal 100TXDN changes from the state 0 to state 1, as shown in the lower part of FIG. 7A, for example, the output signal Vout begins to drop to −1.0 V in a step-by-step manner. The signal decreases by a voltage potential corresponding to a weighting of 2, (i.e., vf₂). For decreasing the signal by vf₂, the second set of current sources is enabled to provide a current for producing the weighted voltage, thus causing the signal to reach a value of −vf₂. After a step period, the signal decreases by a voltage corresponding to the weighting of 4, and thus reaches a voltage of −vf_{2-vf}₄. The signal continues to drop to −1.0 V in a step-by-step manner. When the signal reaches −1.0 V, the decrements of voltages that correspond to the weightings 2, 4, 6, 8, 8, 6, 4, and 2 are all produced. In terms of the notation of vfᵢ, the relationship can be expressed by Vout=−vf₂−vf₄−vf₆−vf₈−vf₈−vf₆−vf₄−vf₂=−1.0 V. After the signal reaches the point of −1.0 V for a number of step periods (which depends on the pulse width of the pulses in the adjustment signal 625a and 625b), it begins to rise to zero voltage in a step-by-step manner because the current sources corresponding to the decrements of voltages begin to be disabled, consecutively. According to the transition of the pulses from the state 1 to state 0, the current sources controlled by the pulses 100(0), 100(1), . . . , and 100(7) are to be disabled successively. For example, the signal, immediately after having a voltage of −1.0 V for the few step periods, increases by a voltage corresponding to the weighting of 2 (i.e. vf₂), by disabling the associated current sources among the second set of current sources corresponding to the step for vf₂. Likewise, the signal returns to 0 V when the current sources for providing currents for the decrements of voltages corresponding to the weightings of 2, 4, 6, 8, 8, 6, 4, and 2 are all disabled. In terms of the notation of vfᵢ, the relationship can be expressed by Vout=−1.0+vf₂+vf₄+vf₆+vf₈+vf₈vf₆+vf₄+vf₂=0. Therefore, the waveform compliant with 100 Base-T can be produced approximately according to the invention.

Note that the scales adopted in FIGS. 7B and 8B are different. For a 10 Base-T signal having an amplitude of 2.5 V as shown in FIG. 7B, voltage increments corresponding to a sum of the weightings of 2, 6, 9, 11, 12 correspond to a total increment of voltage of 2.5 V. As to a 100 Base-T signal, its amplitude is 1.0 V as shown in FIG. 8B, voltage increments corresponding to a sum of the weightings of 2, 4, 6, 8, 8, 6, 4, 2 correspond to a total increment of voltage of 1.0 V. Thus, for the approximation to signals at different data transfer rates, in this embodiment, two weightings used in two different data rates may be of the same value but correspond to different output voltage differences.

Table 1 lists an example of association between the pulses in the adjustment signals and the current sources to be turned on when the data transfer rate is 10 Mbps. In this embodiment, an individual current source mx is capable of producing a current corresponding to a weighting of x for 10 Base-T. Column 1 of table 1 lists the pulses that are fed into the differential amplifier module 650. Column 2 lists the current source(s) that each pulse in column 1 controls. Column 3 lists the associated weightings for the output voltage potential. Note that weightings with negative sign (−) in table 1 are indicative of decrements of voltages. For instance, in the first row, when the pulse 10(0) in the adjustment signal 615a is at the high level and is fed into the transistor Q1 of the differential amplifier module 650, the current source m2 is turned on, resulting in an increment of voltage corresponding to a weighting of 2. When the pulse 10(0) in the adjustment signal 615b is at the high level and is fed into the transistor Q2 of the differential amplifier module 650, the current source m2 is turned on, resulting in a decrement of voltage corresponding to a weighting of 2. For another instance in the second row, when the pulse 10(1) in the adjustment signal 615a is at the high level and is fed into the transistor Q1 of the differential amplifier module 650, the current sources m2 and m4 are turned on, resulting in an increment of voltage corresponding to a weighting of 6. When the pulse 10(1) in the adjustment signal 615b is at the high level and is fed into the transistor Q2 of the differential amplifier module 650, the current sources m2 and m4 are turned on, resulting in a decrement of voltage corresponding to a weighting of 6. In this way, the weightings corresponding to the voltage differences can be obtained according to Table 1. By using appropriate circuit design and the sinusoidal waveforms, associations between weightings and required output voltages can be defined. For instance, the weighting of 12 represents an increment of voltage equal to (12/40)*2.5 V=0.75 V; the weighting of −12 represents a decrement of voltage equal to 0.75 V; the weighting of −6 represents a decrement of voltage equal to 0.375 V. Thus, the nearest approximations to 10 Base-T signals can be produced, corresponding to 10TXD signals.

TABLE 1

| Pulses in adjustment signal 615a; | Current source(s) to be | Associated |
|---|---|---|
| 615b | turned on | weightings |
| pulse 10(0) | m2 | 2; −2 |
| pulse 10(1) | m2, m4 | 6; −6 |
| pulse 10(2) | m3, m6 | 9; −9 |
| pulse 10(3) | m3, m8 | 11; −11 |
| pulse 10(4) | m4, m8 | 12; −12 |
| pulse 10(5) | m4, m8 | 12; −12 |
| pulse 10(6) | m3, m8 | 11; −11 |
| pulse 10(7) | m3, m6 | 9; −9 |
| pulse 10(8) | m2, m4 | 6; −6 |
| pulse 10(9) | m2 | 2; −2 |

Table 2 lists an example of association between the pulses in the adjustment signals and the current sources to be turned on when the data transfer rate is 100 Mbps. Column 1 of table 2 lists the pulses that are fed into the differential amplifier module 650. Column 2 lists the current source that the pulses in column 1 can control. Column 3 lists the associated weightings for the output voltage potential. Note that weightings with negative sign (−) in table 2 are indicative of decrements of voltages. For instance, in the first row, when the pulse 100(0) in the adjustment signal 625a is at the high level and is fed into the transistor Q1 of the differential amplifier module 650, the current source m2 is turned on, resulting in an increment of voltage corresponding to a weighting of 2. When the pulse 100(0) in the adjustment signal 625b is at the high level and is fed into the transistor Q2 of the differential amplifier module 650, the current source m2 is turned on, resulting in a decrement of voltage corresponding to a weighting of 2. In this way, the weightings corresponding to the voltage changes in the approximations can be obtained, according to table 2. By using appropriate circuit design, associations between weightings and required output voltages can be defined. For instance, the weighting of 8 represents an increment of voltage equal to (8/40)*1.0 V=0.2 V; the weighting of −8 represents a decrement of voltage equal to 0.2 V; the weighting of 6 represents an increment of voltage equal to 0.15 V.

TABLE 2

| Pulse in adjustment | Current source to be turned | Associated |
|---|---|---|
| signal 625a; 625b | on | weightings |
| pulse 100(0) | m2 | 2; −2 |
| pulse 100(1) | m4 | 4; −4 |
| pulse 100(2) | m6 | 6; −6 |
| pulse 100(3) | m8 | 8; −8 |
| pulse 100(4) | m8 | 8; −8 |
| pulse 100(5) | m6 | 6; −6 |
| pulse 100(6) | m4 | 4; −4 |
| pulse 100(7) | m2 | 2; −2 |

In particular, a 10 Base-T signal has an amplitude of 2.5 V and a 100 Base-T signal has an amplitude of 1.0 V. The current source module 660, in practice, can be designed to produce a current corresponding to an output voltage of 2.5 V from the differential amplifier module by switching on all of its current sources, for example, all of the 18 current sources listed in the second column of TABLE 1. The current source module can be designed to produce a current corresponding to an output voltage of 1.0 V from the differential amplitude module by switching on a portion of its current sources, that is, those 8 current sources listed in the second column of table 2. Therefore, a 100 Base-T signal can be produced by using a subset of the current sources for 10 Base-T, thereby allowing a shareable signal conversion circuit for both 10 Base-T and 100 Base-T. Since this structure is capable of producing a plurality of weighted voltages according to the requirement for MLT-3 and Manchester encoded signal conversion, the die size can be significantly reduced.

To sum up, different values of current can be provided by sharing one current source module, for generating a plurality of signals, including 10 Base-T and 100 Base-T signals. Since 100 Base-T signal has smaller amplitude than 10 Base-T signal, the number of current sources required for 100 Base-T signal is smaller than that for 10 Base-T signal. Accordingly, 100 Base-T signal can be generated by selectively enabling a portion of the current sources of the current source module. Relatively, 10 Base-T signal has larger amplitude, the number of required current sources is larger and thus more current sources in the current source module need to be turned on. Therefore, the output voltages for the approximations to 10 Base-T and 100 Base-T waveforms can be produced by controlling the current source module according to the pulses in the adjustment signals. Thus, for complying with two data transfer rates, it is unnecessary for the Ethernet/fast-Ethernet network interface card to employ two different tranceivers. Instead, one tranceiver can be designed according to the invention for producing the output signal, thereby saving chip area. Further, the invention can apply to other data transfer rate such as 1 Gbps (giga bit per second) or combination of different data transfer rates such as 100 Mbps/1 Gbps or 10 Mbps/100 Mbps/Gbps.

In brief, the concept of weighting is introduced into the operation of the digital-to-analog conversion device to produce different output signals (i.e., the output voltage Vout) through the association between different weightings and the output required voltages.

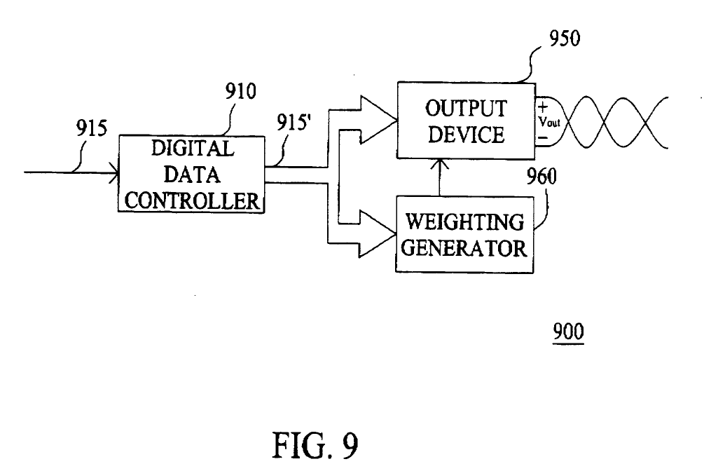

FIG. 9 illustrates a digital-to-analog conversion device according to the invention. The digital-to-analog conversion device 900 is used for converting a digital data stream 915 into an analog output signal Vout, wherein the digital data stream 915 is either a 10TXD signal based on Manchester encoding or a pair of signals: a 100TXD signal and a 100TXDN signal, based on MLT-3 encoding. The digital-to-analog conversion device 900 includes a digital data controller 910, an output device 950, and a weighting generator 960. The digital data controller 910 is coupled to the output device 950 and the weighting generator 960, and the weighting generator 960 is coupled to the output device 950. The digital data controller 910 is capable of converting the digital data stream 915 into an adjustment signal 915′. The adjustment signal 915′ is fed into the output device 950 and the weighting generator 960. On receiving the adjustment signal 915′, the weighting generator 960 feeds the weightings for the adjustment signal 915′ into the output device 950 so that the output device 950 produces the analog output signal Vout based on the adjustment signal 915′ and the associated weightings outputted by the weighting generator 960. If the associated weightings change, the pattern of the output signal Vout changes. Thus, by making an appropriate relationship between the adjustment signal 915′ and its associated weightings, a required output signal, for example, either 10 Base-T signal or 100 Base-T signal, can be obtained. The output device 950 can be an amplifier. The weighting generator 960 can be a current source module for supplying biasing currents to the amplifier. The weighting generator 960 is to feed different biasing currents into the output device 950 so that the output device 950 outputs different output signal Vout based on the biasing currents. Thus, the biasing currents from the weighting generator 960 are in a pattern of weightings, and the pattern of weightings determines the output signal of the output device 950. In practice, the adjustment signal 915′ can be produced by sampling the digital data stream 915 with a plurality of clock signals with different phases. On receiving the adjustment signal 915′, the output device 950 outputs the required output signal Vout. On the other hand, after receiving the adjustment signal 915′, for the requirement of design, the weighting generator 960 can adjust the output weightings and feed them into the output device 950 so as to cause the output device 950 to change the output signal Vout.

As disclosed above, the integrated apparatus for signal transmission has at least the following advantages of: (1) capable of using one transceiver for signal processing of different formats, e.g., 10 Base-T and 100 Base-T, and 1000 Base-T, thus resulting in a reduction in chip area and enhancing competitiveness; and (2) capable of reducing stray capacitance in the output, thus causing impedance match and improving transmission efficiency.

It should be noted that the design parameters used above are only an example of the invention. These design parameters are to exemplify the invention and are not to provide any limitation on the invention. One who is skilled in the art can make modifications of the design parameters so as to obtain the achievements of the invention without departing from the spirit of the invention.

While the invention has been described by way of example and in terms of a preferred embodiment, it is to be understood that the invention is not limited thereto. On the contrary, it is intended to cover various modifications and similar arrangements and procedures, and the scope of the appended claims therefore should be accorded the broadest interpretation so as to encompass all such modifications and similar arrangements and procedures.

What is claimed is:

1. An integrated apparatus for signal transmission, comprising:
a first controller, for receiving a first signal and outputting a first adjustment signal based on the first signal;
a second controller, for receiving a second signal and outputting a second adjustment signal based on the second signal;
a decoding device, coupled to the first controller and the second controller, for outputting a selected adjustment signal selected from the first adjustment signal and the second adjustment signal; and
a driving device, coupled to the decoding device, for producing either a first output signal according to the first adjustment signal, or a second output signal according to the second adjustment signal, in response to said selected adjustment signal.

2. The integrated apparatus according to claim 1, wherein the first controller is an Ethernet controller and the second controller is a fast-Ethernet controller.

3. The integrated apparatus according to claim 2 wherein the first signal is compliant with Manchester encoding.

4. The integrated apparatus according to claim 3, wherein the first signal is a 10TXD signal.

5. The integrated apparatus according to claim 2, wherein the first signal is sampled by a first sampling signal to generate the first adjustment signal.

6. The integrated apparatus according to claim 5, wherein the first sampling signal includes a plurality of clock signals with different phases.

7. The integrated apparatus according to claim 2, wherein the first output signal is a 10 Base-T signal.

8. The integrated apparatus according to claim 2, wherein the second signal is compliant with MLT-3 encoding.

9. The integrated apparatus according to claim 8, wherein the second signal includes a 100TXD signal and a 100TXDN signal.

10. The integrated apparatus according to claim 2, wherein the second adjustment signal is produced by sampling the second signal through a second sampling signal.

11. The integrated apparatus according to claim 10, wherein the second sampling signal includes a plurality of clock signals with different phases.

12. The integrated apparatus according to claim 2, wherein the first output signal is a 100 Base-T signal.

13. The integrated apparatus according to claim 2, wherein the driving device comprises:
an amplifier coupled to the decoding device, wherein the amplifier is driven by either the first adjustment signal or the second adjustment signal; and
a current source module, coupled to the decoding device and the amplifier, for supplying an operating current to the amplifier according to either the first adjustment signal or the second adjustment signal, wherein when the current source module, according to the first adjustment signal, outputs the operating current, the amplifier produces the first output signal, and when the current source module, according to the second adjustment signal, outputs the operating current, the amplifier produces the second output signal.

14. The integrated apparatus according to claim 13, wherein the first signal is compliant with Manchester encoding.

15. The integrated apparatus according to claim 14, wherein the first signal is a 10TXD signal.

16. The integrated apparatus according to claim 13, wherein the first adjustment signal is produced by sampling the first signal through a first sampling signal.

17. The integrated apparatus according to claim 16, wherein the first sampling signal includes a plurality of clock signals with different phases.

18. The integrated apparatus according to claim 13, wherein the first output signal is a 10 Base-T signal.

19. The integrated apparatus according to claim 13, wherein the second signal is compliant with MLT-3 encoding.

20. The integrated apparatus according to claim 19, wherein the second signal includes a 100TXD signal and a 100TXDN signal.

21. The integrated apparatus according to claim 13, wherein the second adjustment signal is produced by sampling the second signal through a second sampling signal.

22. The integrated apparatus according to claim 21, wherein the second sampling signal includes a plurality of clock signals with different phases.

23. The integrated apparatus according to claim 13, wherein the first output signal is a 100 Base-T signal.

24. The integrated apparatus according to claim 13, wherein the amplifier is a differential amplifier.

25. A method for performing digital-to-analog conversion on a digital data stream to output an output signal, the method comprising the steps of:
sampling the digital data stream so as to produce an adjustment signal; and
producing the output signal based on a plurality of weightings in response to the adjustment signal.

26. The method according to claim 25, wherein the output signal is a 10 Base-T signal.

27. The method according to claim 25, wherein the digital data stream includes a 100TXD signal and a 100TXDN signal.

28. The method according to claim 25, wherein the output signal is a 100 Base-T signal.

29. The method according to claim 25, wherein the digital data stream is sampled by a sampling signal which includes a plurality of clock signals with different phases.
